(19) United States
(12) Patent Application Publication
(10) Pub. No.: US 2010/0141281 A1
(43) Pub. Date: Jun. 10, 2010

(54) WATER DETECTOR

(76) Inventor: Asle Ingemar Johnsen, Tonsberg (NO)

Correspondence Address: BIRCH STEWART KOLASCH & BIRCH, PO BOX 747, FALLS CHURCH, VA, 22040-0747, US

(21) Appl. No.: 12/666,718

(22) PCT Filed: Jun. 2, 2008
(86) PCT No.: PCT/NO2008/000197

§ 371 Date: Jan. 27, 2010

(30) Foreign Application Priority Data
Jun. 28, 2007 (NO) 2007 3343

(51) Int. Cl. G01R 27/08; G01N 27/04

(52) U.S. Cl. 324/694

(57) ABSTRACT

A detector system is provided suited for detection of environmental effects. The sensing element is constructed in the form of a grid and is designed in particular for the detection of moisture. Said structure is suited for simple deployment, optionally embedding into concrete, and detection of environmental effects on a large scale such as tunnels, bridges, dams and quays.

### CROSS REFERENCE TO RELATED APPLICATION

This application claims priority to Norwegian Patent Application 2007 3343, filed 28 Jun. 2007.

### FIELD OF THE INVENTION

This invention relates to a detector system comprising structures for detection of environmental effects.

### BACKGROUND

From prior art one should refer to traditional moisture detectors such as detectors based on changes in electrical conductive properties of materials absorbing moisture, probes for capacity detection of moisture, optical detection of liquids and detection of liquids by short circuiting of electrodes. The disadvantageous of the above mentioned methods are numerous. Devices are typically hand held devices equipped with probes, put into direct contact with material to be investigated for moisture. Solutions based on moisture absorbing materials will experience chemical corrosions of a time, optical methods require typically moistures at such levels that liquids will be present in free form, and devices based on electrical contact with water require relatively large amounts of water and may also experience problems with electrical corrosion and other forms of corrosion.

Typically for these embodiments are that these are independent units measuring moisture in clearly defined positions. Costs are frequently major and are not suitable for large scale deployment.

### PROBLEMS TO BE SOLVED BY THE INVENTION

Based on the state of the known art the purpose of the invention is to provide a robust structure for monitoring of large areas at low cost, that can be deployed simply, can be embedded into structures such as buildings as well as cement and concrete, and is also suitable for simple production and monitoring.

### SUMMARY OF THE INVENTION

According to the invention this objective is achieved by a detector system comprising one or more detection tracks arranged in a substantially fixed distance in a structure of a substantially insulating material, optionally in the embodiment as one or more fishing net like modules that can be connected together to other larger areas wherein each module comprises one net structure with one or more longitudinal detection tracks in one direction, optionally in two directions that are substantially normal to each other in such a way that a substantially rectangular structure is formed wherein each end or each of the four sides are terminated by a contact for attachment to adjacent similar modules, optionally end termination to a readout network. In a typical embodiment this structure is formed as wires on a foil material. In another embodiment this structure is embodied as a series of wires optionally intersecting each other wherein each intersection can optionally be stabilized using a stabilizing device.

### BRIEF DESCRIPTION OF THE DRAWINGS

FIG. 1 shows a typical embodiment of a detector system according to the invention wherein each module is interconnected in order to cover a larger area.

FIG. 2 shows a module with wires, termination and contacts.

FIG. 3 shows a cross-section of an embodiment of a wire used in a fishing net like structure.

FIG. 4 shows a detail where two wires intersect each other, stabilized in the area of intersection.

### DETAILED DESCRIPTION OF EMBODIMENTS

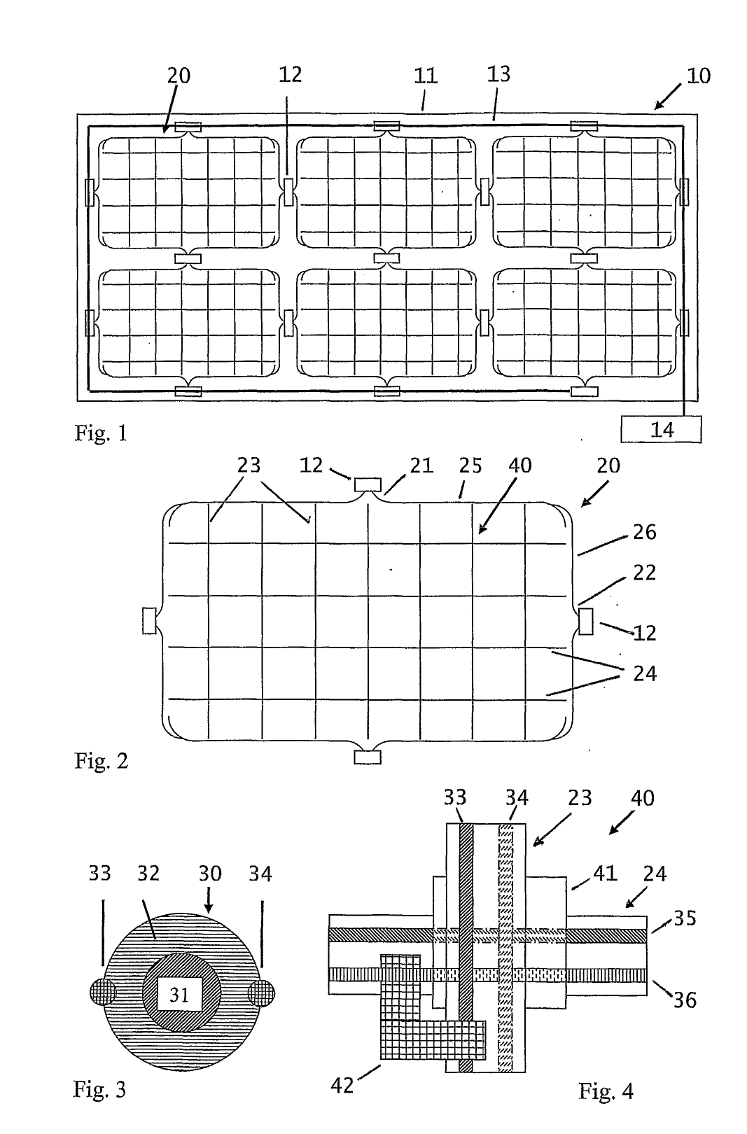

The invention will be disclosed with reference to the drawings wherein FIG. 1 shows the detector system in a typical embodiment. An installation 10 comprises six modules 20 in order to monitor an area 11. Each module 20 is interconnected with its nearest neighbour using a connection device 12. The modules 20 are also connected to a databus 13 which again conveys signals to a monitoring unit 14.

FIG. 2 shows a single module comprising a first end contact 21 which terminals a plurality of wires 23 using an interconnect 25. Correspondingly in a direction substantially perpendicular to the end contact 21 a second end contact 22 is provided, terminating plurality of wires 24 via an interconnect 26.

Such a module can be executed in a number of embodiments, in one embodiment as conductors on a substrate, typically embodied as printed conductors on for instance an acetate, a flexible foil suited for lying of the structures such as inside ceilings where the foil is transported on rolls and rolled out in the necessary length and cut according to needed. Such an embodiment with a suited substrate may also operate with a diffusion barrier, for instance provided inside in buildings. In a second embodiment the module is provided as a series of wires in a mask like structure not entirely dissimilar to a fishing net. This embodiment is suited for inserting into a casting, concrete, plastic or similar materials. In order to provide mechanical stability and breaking strength it is important that there are no sharp corners or other structures with small radii of curvature.

FIG. 3 shows a cross-section of a wire 23, 24 where said wire 30 comprises two electrical conductors 33 and 34 arranged in an electrical insulating material 32 in such a way that these are not in direct electrical contact with each other. Electrical conductors 33 and 34 are arranged along the surface of the insulating material 32 where this is environmentally possible, however in a corrosive environment it is an advantage that the insulating material 32 also encapsulates the conductors 33 and 34. Optionally also a functional material 31 can be provided in the core of the insulator 32. Moisture is detected by measuring changes in the capacitance between the conductors 33 and 34. Such a change in capacitance is advantageously measured using an AC current. An optionally functional material 31 can also be used in order to measure other properties resistibly, for instance temperature using a material which changes electrical resistivity based on temperature. By using a structure as shown in FIG. 3 the resistivity can be measured without disturbing capacitance by applying a DC voltage across the conductors 33 and 34 and thus measure leakage current passing through the core 31. Where the wire 30 is along the leakage current from conductor 33 through insulator 32 to functional material 31 and from there again through insulator 32 to conductor 34 will be sufficient in order to provide a readable signal. Optionally a resistor part can be provided between conductor 33 and a functional material 31 and between conductor 34 and first known electrical material 31. Thus it is possible to measure a plurality of parameters using the same wire structure. Alternatively moisture can be measured resistibly between the conductors 33 and 34 where conductors are partially uninsulated. The insulator 32 can alternatively be arranged as an optical fiber for transmission of high speed signals across long distances. Such a fiber can also function as a sensor by measuring optical properties such as optical loss, refraction and dispersion. The fiber can be arranged with a combination of functional materials in the core of the fiber and the sheet around the fiber for the measurement of optical properties when the functional materials changes properties such as swelling on intake of moisture and the changes in the refractive index by contact with chemicals.

FIG. 4 shows an intersection 40 between a wire 23 and a wire 24 where these intersection each other. By providing a support structure 41 between the wires stability is assured in the mask structure. The support structure 41 can also be provided with a first functional material where further environmental effects such as but not limited to chemical effects, smoke, mechanical changes and vibrations can be measured by measuring the resistance between a conductor 34 in the wire 23 and a second electrical conductor 35 in the second wire 24. By further providing and element 42 connecting a conductor 33 in the wire 23 and a second electrical conductor 36 in the second wire 24 with a second functional material further types of environmental effects can be detected. Also regarding functional materials such as in the support structure 41 and the element 42 it can be advantageous either to remove the insulation between the conductors 33, 34, 35 and 36 or to provide a resistive part between the conductors and support structure 41 and the element 42. The support structure 41 and the element 42 are not limited to be sensors, but can also but not limited be a current supply to other functions such as indicators, alarms, signal amplifiers, fault location and more. Wires can be provided with conductors twisted in a spiral pattern and thus transmit high frequency signals across long distances without degradation of signals, for instance for use in networks and other sonic components. If the conductors are twisted by twisting the entire wire, this can be stabilized using the support structure 41.

The monitoring unit 14 monitors by operating on the at least one module 20 typically in a plurality of modi sequentially. In a first mode an AC voltage is applied and the monitoring unit measures changes in impedance that arises when moisture increases the dielectric permittivity for the capacitive effect that arises between the two conductors 33 and 34. In a second mode a DC current is supplied, and the resistance between the functional material 31 is measured. In a third mode a voltage supplied on a first conductor 34 on the first wire 23 and a first conductor 35 on the second wire 24 in order to measure an electrical property such as the resistance in the functional material 41 between the conductors 34 and 35. In a forth mode a voltage is supplied on a second conductor 33 of the first wire 23 and on a second conductor 36 on the second wire 24 in order to measure an electrical property such as the resistance in a functional material 42 which is arranged between the conductor 33 and 36. The distance through the functional material 42 is typically longer than through the functional material 41, and it may therefore be advantageous to use this mode for current supply to other functions or signaling through for instance light emitting diodes. Certain modes can be combined for instance the first mode and the second mode by applying an AC voltage with a DC offset. Wires may be monitored separately or several at the same time, sequentially or continuously. Wires can also be exempted from monitoring in order to maintain reserves till special needs appear such as where adjacent wires are worn out. This is particularly advantageous where wires are subjected to wear such as through electrical corrosion.

By using optical fiber the monitoring unit 14 may use separate modes for these. In a first optical mode pulses are emitted and the intensity of received reflected pulses are measured in order to measure changes in optical refractive index. In a second mode light is entered into one end of a fiber and transmitted light measured in a second end of the fiber. From the known art methods are well known for measurement using fiber optical sensors, properties such as electrical and magnetic fields, pressure, temperature, acoustic, vibration, linear- and angular position, tension and moisture.

During installation the monitoring unit will provide fault location information and will perform calibration of the system. The monitoring unit reports measurements to external units for instance through a network.

Functional materials may for instance be materials that changes resistance with temperature or chemical action, strain gauges measuring mechanical effects or breakable electrical collections that break when a threshold for mechanical, thermal or electrical effects are crossed. Breakable electrical connections will provide information regarding events even where the events are taken place in periods between two measurements. This enables slow and thereby accurate measurements and thereby detect even small changes in electrical characteristics.

Modules are connected using connection devices 12. Such a connection can be passive in such a way that connected modules appear electrically like a large module. During installation it can be advantageous to use a first type active connection in order to verify that the module is free from errors and that signals are passing through all interconnected modules. For larger systems a second type active connection can be useful where signals are amplified in order to enable signals to operate across along distances. In such a case these may be provided with current when the monitoring unit operates a first part of a module in a fourth module and a second part of the module in a second module. A third type active connection can be arranged along the interconnected modules in order to convert the typical parallel signals in the modules to serial data for further transmission along the data bus 13, thereby reducing the number of necessary wires. A fourth type connection can provide rerouting of signals in order to route around defects in one track in a module in such a way that the effects of defects only affect the module where the defect took place and not the attached modules. A fifth type connection provides also the optical connection, optionally also optical/electrical conversion. As an alternative to the data base 13 signals from the edges of the modules can be transmitted wirelessly.

### INDUSTRIAL APPLICABILITY

According to the invention is suited for monitoring of moisture inside houses, monitoring structures such as tunnels, bridges, dams and quays for water intrusion and chemical effects such as leakages and corrosion, and mechanical effects such as avalanches, monitoring of temperature, for instance connected to a fire alarm system for leading people in the optimal direction during fire evacuation as well as monitoring breakage in larger structures.

In an embodiment as a wire structure with wires in one direction, this can be used for monitoring for instance tunnels, where a danger discovered in any one wire can be a reason for closing down the tunnel.

In an embodiment as a fishing net like structure, with wires in two directions, an environmental effect can be located by cross bearing and localized with a resolution depending on the size of the masks in the mask structure.

1. A detection system, wherein it comprises two or more tracks arranged with a substantially fixed mutual distance in a structure of a substantially insulating material, wherein the tracks are longitudinal detection tracks in one direction, optionally two directions wherein tracks are substantially 90° to each other, wherein each track detects an environmental effect in proximity of the track.

2. System according to claim 1, wherein tracks are printed as electrical conductors on an insulating substrate.

3. System according to claim 2, wherein the substrate is flexible.

4. System according to claim 2, wherein the substrate is a diffusion barrier.

5. System according to claim 1, wherein the structure is open in that the tracks are arranged as wires in a fishing net like structure, wherein each wire comprises a first electrical conductor and a second electrical conductor, within said two electrical conductors are separated from each other by an electrical insulator.

6. System according to claim 2, wherein the insulating is arranged with a functional material in the core located substantially between the electrical collectors so that the environmental effects on the functional material will change the electrical properties readable from the electrical conductors.

7. System according to claim 1, wherein a functional material is arranged between at least two conductors belonging to two tracks where said tracks intersects each other in such a way that the environmental on the functional material change electrical properties readable by the electrical conductors.

8. System according to claim 1, wherein the structure is at least a module provided with end contacts along the periphery for connection to further modules.

9. System according to claim 1, wherein the structure is arranged for operating in a plurality of modes comprising AC current mode, DC current mode, a third mode for applying a voltage of a first conductor on a first wire and on a first wire on a second wire, and a fourth mode by applying a voltage on a second conductor on the first wire and on the second conductor on the second wire; for measuring values such as impedance and resistance, as well as for current supply.

10. System according to claim 3, wherein the substrate is a diffusion barrier.

11. System according to claim 3, wherein the insulating is arranged with a functional material in the core located substantially between the electrical collectors so that the environmental effects on the functional material will change the electrical properties readable from the electrical conductors.

12. System according to claim 4, wherein the insulating is arranged with a functional material in the core located substantially between the electrical collectors so that the environmental effects on the functional material will change the electrical properties readable from the electrical conductors.

13. System according to claim 5, wherein the insulating is arranged with a functional material in the core located substantially between the electrical collectors so that the environmental effects on the functional material will change the electrical properties readable from the electrical conductors.

14. System according to claim 2, wherein a functional material is arranged between at least two conductors belonging to two tracks where said tracks intersects each other in such a way that the environmental on the functional material change electrical properties readable by the electrical conductors.

15. System according to claim 3, wherein a functional material is arranged between at least two conductors belonging to two tracks where said tracks intersects each other in such a way that the environmental on the functional material change electrical properties readable by the electrical conductors.

16. System according to claim 4, wherein a functional material is arranged between at least two conductors belonging to two tracks where said tracks intersects each other in such a way that the environmental on the functional material change electrical properties readable by the electrical conductors.

17. System according to claim 5, wherein a functional material is arranged between at least two conductors belonging to two tracks where said tracks intersects each other in such a way that the environmental on the functional material change electrical properties readable by the electrical conductors.

18. System according to claim 6, wherein a functional material is arranged between at least two conductors belonging to two tracks where said tracks intersects each other in such a way that the environmental on the functional material change electrical properties readable by the electrical conductors.

19. System according to claim 2, wherein the structure is at least a module provided with end contacts along the periphery for connection to further modules.

20. System according to claim 3, wherein the structure is at least a module provided with end contacts along the periphery for connection to further modules.
